(19) United States
(12) Patent Application Publication
(10) Pub. No.: US 2026/0142632 A1
(43) Pub. Date: May 21, 2026

(54) MULTI-LOOP CONTROL CIRCUIT AND CONTROL METHOD THEREOF

(71) Applicant: ANPEC ELECTRONICS CORPORATION, HSINCHU (TW)

(72) Inventors: FU-CHUAN CHEN, Hsinchu City (TW); HSUEH-EN HAN, Hsinchu City (TW)

(21) Appl. No.: 19/046,568

(22) Filed: Feb. 6, 2025

(30) Foreign Application Priority Data
Nov. 21, 2024 (TW) 113144785

(51) Int. Cl. H03F 3/45

(52) U.S. Cl. CPC H03F 3/45475; H03F 2200/129

(57) ABSTRACT

A multi-loop control circuit and a control method thereof. The multi-loop control circuit includes an amplification stage circuit and a current selection circuitry. The amplification stage circuit includes a first operational transconductance amplifier that outputs a first transconductance amplification current and a second operational transconductance amplifier that outputs a second transconductance amplification current. The current selection circuitry receives the first transconductance amplification current and the second transconductance amplification current to output an error output current. The current selection circuitry selects and outputs a largest one among the first transconductance amplification current and the second transconductance amplification current as the error output current, and an error amplification signal is generated from the error output current.

### CROSS-REFERENCE TO RELATED PATENT APPLICATION

This application claims the benefit of priority to Taiwan Patent Application No. 113144785, filed on Nov. 21, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a control circuit, and more particularly to a multi-loop control circuit and a control method thereof.

### BACKGROUND OF THE DISCLOSURE

A common structure of existing multi-loop control circuits includes multiple error amplifiers having output terminals connected in parallel, and an error amplification signal at the output terminals is determine based on the voltage difference at input terminals of each of the error amplifiers. For the multi-loop control circuit, based on the relative size of the error amplification signals in the error amplifiers, one of the error amplifiers is determined to be used for feedback control.

The multi-loop control circuits generally include multiple error amplifiers, and the error amplifiers usually include operational transconductance amplifier (OTA) and buffers. Since the buffers generally occupy a large area in the circuit design, such designs are not conducive to the miniaturization of the multi-loop control circuits.

### SUMMARY OF THE DISCLOSURE

In response to the above-referenced technical inadequacies, the present disclosure provides a multi-loop control circuit and a control method of the multi-loop control circuit.

In order to solve the above-mentioned problems, one of the technical aspects adopted by the present disclosure is to provide a multi-loop control circuit. The multi-loop control circuit includes an amplification stage circuit and a current selection circuitry. The amplification stage circuit including a first operational transconductance amplifier and a second operational transconductance amplifier. The first operational transconductance amplifier generates a first transconductance amplification current at an output terminal based on a voltage difference at input terminals. The second operational transconductance amplifier generates a second transconductance amplification current at an output terminal based on a voltage difference at input terminals. The current selection circuitry receives the first transconductance amplification current and the second transconductance amplification current to output an error output current. The current selection circuitry selects and outputs a largest one among the first transconductance amplification current and the second transconductance amplification current as the error output current, and an error amplification signal is generated from the error output current.

In order to solve the above-mentioned problems, another one of the technical aspects adopted by the present disclosure is to provide a control method of multi-loop control circuit. The control method includes the following steps of: comparing, by using a current selection circuitry, a first transconductance amplification current output by a first operational transconductance amplifier and a second transconductance amplification current output by a second operational transconductance amplifier; outputting, by using the current selection circuitry, an error output current based on a result of the comparison; the error output current being a largest one among the first transconductance amplification current and the second transconductance amplification current; and converting the error output current into an error amplification signal.

Therefore, in the multi-loop control circuit and the control method of the multi-loop control circuit provided by the present disclosure, by the design of the current selection circuitry being disposed in the multi-loop control circuit, a quantity of the buffers that are used can be decreased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a multi-loop control circuit according to one embodiment of the present disclosure;

FIG. 2 is a schematic diagram of a current selection circuitry according to one embodiment of the present disclosure;

FIG. 3 is a schematic diagram of an amplification stage circuit according to one embodiment of the present disclosure;

FIG. 4 is another schematic diagram of the multi-loop control circuit according to one embodiment of the present disclosure;

FIG. 5 is a flowchart of a control method of the multi-loop control circuit according to one embodiment of the present disclosure;

FIG. 6 is a schematic diagram comparing waveforms of transconductance amplification currents and an error output current according to one embodiment of the present disclosure; and

FIG. 7 is a schematic diagram comparing waveforms of reference voltages and error amplification signals according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Embodiments of the present disclosure provide a multi-loop control circuit and a control method of the multi-loop control circuit. The multi-loop control circuit can control the output of multiple operational transconductance amplifiers (OTA), thereby allowing error amplification signals to track synchronous changes in voltage under specified conditions. It should be noted that this embodiment uses a circuit design method that compares the output current of each of the operational transconductance amplifiers, so as to effectively reduce the number of buffers and reduce power consumption.

### Example of Usage Architecture of the Multi-Loop Control Circuit

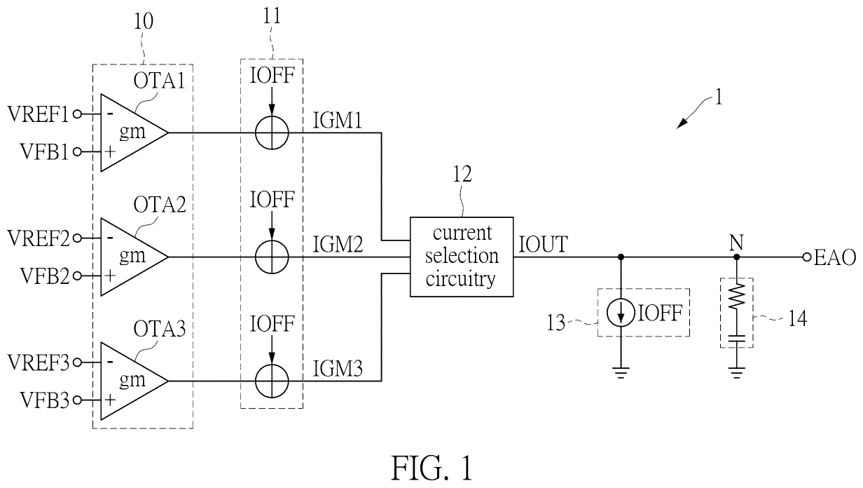

Reference is made to FIG. 1, which is a schematic diagram of a multi-loop control circuit according to one embodiment of the present disclosure. A multi-loop control circuit 1 in this embodiment includes an amplification stage circuit 10 and a current selection circuitry 12. The amplification stage circuit 10 can output multiple sets of transconductance amplification currents, and the current selection circuitry 12 selects one set of the multiple sets of transconductance amplification currents to output as an error output current IOUT, and an error amplification signal EAO is generated according to the error output current IOUT. In one embodiment, the voltage level of the error amplification signal EAO can track changes of an input voltage and be changed synchronously, and the input voltage can be one of multiple reference voltages input to the amplification stage circuit 10. For example, the input voltage can be a largest or a smallest one among multiple reference voltages.

The amplification stage circuit 10 of the present disclosure includes multiple operational transconductance amplifiers. As shown in FIG. 1, the amplification stage circuit 10 includes a first operational transconductance amplifier OTA1, a second operational transconductance amplifier OTA2, and a third operational transconductance amplifier OTA3. In other embodiments, a quantity of the operational transconductance amplifiers may be other than 3, and the quantity of operational transconductance amplifiers corresponds to the number of error amplification signals EAO tracking the target input voltage.

Furthermore, the first operational transconductance amplifier OTA1 can generate a first transconductance amplification current IGM1 at an output terminal based on a voltage difference at input terminals; the second operational transconductance amplifier OTA2 can generate a second transconductance amplification current IGM2 at an output terminal based on a voltage difference at input terminals; and the third transconductance amplifier OTA3 can generate a third transconductance amplification current IGM3 at an output terminal based on a voltage difference at input terminals.

As shown in FIG. 1, the voltage difference between the input terminals of the first operational transconductance amplifier OTA1 refers to the voltage difference between a first feedback voltage VFB1 received by a non-inverting input terminal and a first reference voltage VREF1 received by an inverting input terminal. The voltage difference between the input terminals of the second operational transconductance amplifier OTA2 refers to the voltage difference between a second feedback voltage VFB2 received by a non-inverting input terminal and a second reference voltage VREF2 received by an inverting input terminal. The voltage difference between the input terminals of the third operational transconductance amplifier OTA3 refers to the voltage difference between a third feedback voltage VFB3 received by a non-inverting input terminal and a third reference voltage VREF3 received by an inverting input terminal. In one embodiment, the first feedback voltage VFB1, the second feedback voltage VFB2, and the third feedback voltage VFB3 are equal to a feedback voltage, and the feedback voltage can be generated by the error amplification signal EAO.

In other embodiments, the voltage difference between the input terminals of the first operational transconductance amplifier OTA 1 refers to the voltage difference between the inverting input terminal receiving the first feedback voltage VFB1 and the non-inverting input terminal receiving the first reference voltage VREF1. The voltage difference between the input terminals of the second operational transconductance amplifier OTA2 refers to the voltage difference between the inverting input terminal receiving the second feedback voltage VFB2 and the non-inverting input terminal receiving the second reference voltage VREF2. The voltage difference between the input terminals of the third operational transconductance amplifier OTA3 refers to the voltage difference between the inverting input terminal receiving the third feedback voltage VFB3 and the non-inverting input terminal receiving the third reference voltage VREF3.

It should be noted that the current selection circuitry 12 in one embodiment selects a largest one from a plurality of transconductance amplification currents as the error output current IOUT. As shown in FIG. 1, the current selection circuitry 12 may select a largest one from the first transconductance amplification current IGM1, the second transconductance amplification current IGM2, and the third transconductance amplification current IGM3 as the error output current IOUT. It should be noted that the current selection circuitry 12 compares various transconductance amplification currents through the design of a switch circuit to determine the largest one of the transconductance amplification currents. Specific structures of the current selection circuitry 12 will be described in detail hereinafter.

In one embodiment, a current compensation circuit 11 is disposed between the output terminal of each of the operational transconductance amplifiers and the input terminals of the current selection circuitry 12. The current compensation circuit 11 performs current compensation on each of the transconductance amplification currents flowing into the current selection circuitry 12, such that each of the compensated transconductance amplification currents has a positive level. As shown in FIG. 1, a compensation current inflow path is added to a path of the first transconductance amplification current IGM1 flowing into the input terminal of the current selection circuitry 12; that is, a compensation current IOFF is added to the first transconductance amplification current IGM1 that is compensated. A compensation current inflow path is added to a path of the second transconductance amplification current IGM2 flowing into the input terminal of the current selection circuitry 12; that is, the compensation current IOFF is added to the second transconductance amplification current IGM2 that is compensated. A compensation current inflow path is added to a path of the third transconductance amplification current IGM3 flowing into the input terminal of the current selection circuitry 12; that is, a compensation current IOFF is added to the first transconductance amplification current IGM1 that is compensated. Here, the compensation current IOFF is positive.

In one embodiment, a current removal circuit 13 is disposed at the output terminal of the current selection circuitry 12. The current removal circuit 13 removes a compensation current of the current compensation circuit 11 from the error output current IOUT that flows out from the current selection circuitry 12, such that the error output current IOUT having the compensation current IOFF removed is equal to an original transconductance amplification current. As shown in FIG. 1, a shunt path for the compensation current IOFF that flows out of the current selection circuitry 12 is added to the path of the output terminal, such that the error output current IOUT minus the compensation current IOFF is transmitted to a next stage circuit through a node N.

In one embodiment, when the transconductance amplification currents output by the operational transconductance amplifier are all positive, the above-mentioned current compensation circuit 11 and the current removal circuit 13 can be omitted.

In one embodiment, a loop compensation circuit 14 is connected to the output terminal of the current selection circuitry 12. Here, the loop compensation circuit 14 includes a compensation resistor and a compensation capacitor that are connected in series. The loop compensation circuit 14 can be used to adjust and stabilize a feedback loop of a circuit system to improve system stability and response speed.

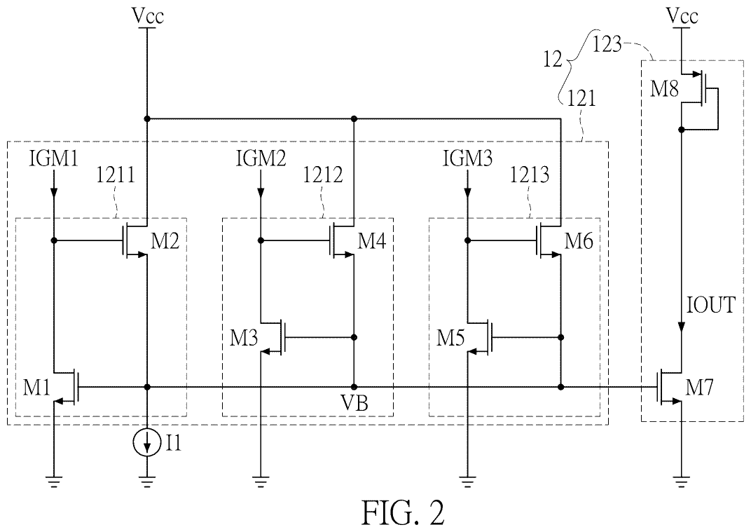

In one embodiment, the current selection circuitry 12 may be as shown in FIG. 2. FIG. 2 is a schematic diagram of a current selection circuitry according to one embodiment of the present disclosure. The current selection circuitry 12 includes a selection circuit 121 and a mapping circuit 123. The selection circuit 121 can select the largest one from multiple transconductance amplification currents, and the mapping circuit 123 maps and outputs the largest one of the transconductance amplification currents as the error output current IOUT.

For example, the selection circuit 121 may include a plurality of switch circuits, where a quantity of the switch circuits is equal to a number of transconductance amplification currents output by the amplifier stage circuit 10. As shown in FIG. 2, the selection circuit 121 includes a first switch circuit 1211, a second switch circuit 1212, and a third switch circuit 1213. The first switch circuit 1211 can generate a first conduction voltage according to the first transconductance amplification current IGM1, the second switch circuit 1212 can generate a second conduction voltage according to the second transconductance amplification current IGM2, and the third switch circuit 1213 can generate a third conduction voltage according to the third transconductance amplification current IGM3. Furthermore, the first switch circuit 1211, the second switch circuit 1212, and the third switch circuit 1213 are connected in parallel to generate conduction current. Here, the conduction current is one of the transconductance amplification currents output by the amplifier stage circuit 10.

Furthermore, when the first transconductance amplification current IGM1 is greater than the second transconductance amplification current IGM2 and the third transconductance amplification current IGM3, the first conduction voltage is greater than the second conduction voltage and the third conduction voltage. The first switch circuit 1211 is turned on according to the first conduction voltage, and the first conduction voltage clamps the second conduction voltage and the third conduction voltage, such that the second switch circuit 1212 and the third switch circuit 1213 are turned off. At this time, the conduction current is the first transconductance amplification current IGM1.

Alternatively, when the second transconductance amplification current IGM2 is greater than the first transconductance amplification current IGM1 and the third transconductance amplification current IGM3, the second conduction voltage is greater than the first conduction voltage and the third conduction voltage, the second switch circuit 1212 is turned on according to the second conduction voltage, and the second conduction voltage clamps the first conduction voltage and the third conduction voltage, such that the first switch circuit 1211 and the third switch circuit 1213 are turned off. At this time, the conduction current is the second transconductance amplification current IGM2.

Alternatively, when the third transconductance amplification current IGM3 is greater than the first transconductance amplification current IGM1 and the second transconductance amplification current IGM2, the third conduction voltage is greater than the first conduction voltage and the second conduction voltage, the third switch circuit 1213 is turned on according to the third conduction voltage, and the third conduction voltage clamps the first conduction voltage and the second conduction voltage, such that the first switch circuit 1211 and the second switch circuit 1212 are turned off. At this time, the conduction current is the third transconductance amplification current IGM3.

It can be understood that the conduction voltage formed by the largest transconductance amplification current in the switch circuit is greater than the conduction voltage of other switch circuits, and only the switch circuit through which the largest transconductance amplification current flows will be turned on, while the other switch circuits will be turned off.

In one embodiment, each of the switch circuits includes a first transistor and a second transistor. For the first switch circuit 1211, a control terminal of a first transistor M1 is connected to a second terminal of a second transistor M2. A first terminal of the first transistor M1 receives the first transconductance amplification current IGM1 and is simultaneously connected to a control terminal of the second transistor M2. A second terminal of the first transistor M1 is connected to a ground terminal, a first terminal of the second transistor M2 receives the power input, and the second terminal of the second transistor M2 is connected to an electrical current source. The components and connection manners of the second switch circuit 1212 and the third switch circuit 1213 are the same as those of the first switch circuit 1211 and will not be reiterated herein.

It should be noted that the control terminals of the first transistors in each of the switch circuits are connected in parallel with each other, and the transistors used in the selection circuit 121 are such as N-channel transistors. In other embodiments, the transistors used in selection circuit 121 can also be P-channel transistors.

For example, the first transistor M1 of the first switch circuit 1211 forms a first conduction voltage at the first terminal and the second terminal of the first transistor M1 based on the first transconductance amplification current IGM1, and the control terminal of the second transistor M2 of the first switch circuit 1211 is controlled by the first conduction voltage; when the second transistor M2 of the first switch circuit 1211 is turned on based on the first conduction voltage, the first transistor M1 of the first switch circuit 1211 is turned on to output the first transconductance amplification current IGM1.

A first transistor M3 of the second switch circuit 1212 forms a second conduction voltage at a first terminal and a second terminal of the first transistor M3 based on the second transconductance amplification current IGM2, and a control terminal of a second transistor M4 of the second switch circuit 1212 is controlled by the second conduction voltage; when the second transistor M4 of the second switch circuit 1212 is turned on based on the second conduction voltage, the first transistor M3 of the second switch circuit 1212 is turned on to output the second transconductance amplification current IGM2.

A first transistor M5 of the third switch circuit 1213 forms a third conduction voltage at a first terminal and a second terminal of the first transistor M5 based on the third transconductance amplification current IGM3, and a control terminal of a second transistor M6 of the third switch circuit 1213 is controlled by the third conduction voltage; when the second transistor M6 of the third switch circuit 1213 is turned on based on the third conduction voltage, the first transistor M5 of the third switch circuit 1213 is turned on to output the third transconductance amplification current IGM3.

Therefore, when the control terminals of the first transistors in each of the switch circuits are connected in parallel with each other, at this time, if the first transconductance amplification current IGM1 is the largest among the transconductance amplification currents, a voltage at the first terminal and the second terminal of the first transistor M1 of the first switch circuit 1211 will be greater than the voltages at the first end and the second end of the first transistor in other switch circuits. Therefore, at this time, the second transistor M2 of the first switch circuit 1211 will be turned on, and the second transistor the other switch circuits will not be turned on. The mapping circuit 123 maps the first transconductance amplification current IGM1 output by the first switch circuit 1211 that is turned on, and the first transconductance amplification current IGM1 is the error output current IOUT output by the current selection circuitry 12.

It can be understood that, the mapping circuit 123 and the first transistor in the switch circuit that is turned on can form a current mirror circuit. That is, a control terminal of a mapping transistor M7 in the mapping circuit 123 is connected to the control terminal of the first transistor in each of the switch circuits. Here, the mapping circuit 123 is such as composed of a stack of a mapping transistor M7 and a transistor M8.

In addition, when the second transconductance amplification current IGM2 or the third transconductance amplification current IGM3 is the largest among the transconductance amplification currents, an operation mode of the switch circuit and the mapping circuit 123 at this time is the same as that described in the previous embodiments, and will not be reiterated herein.

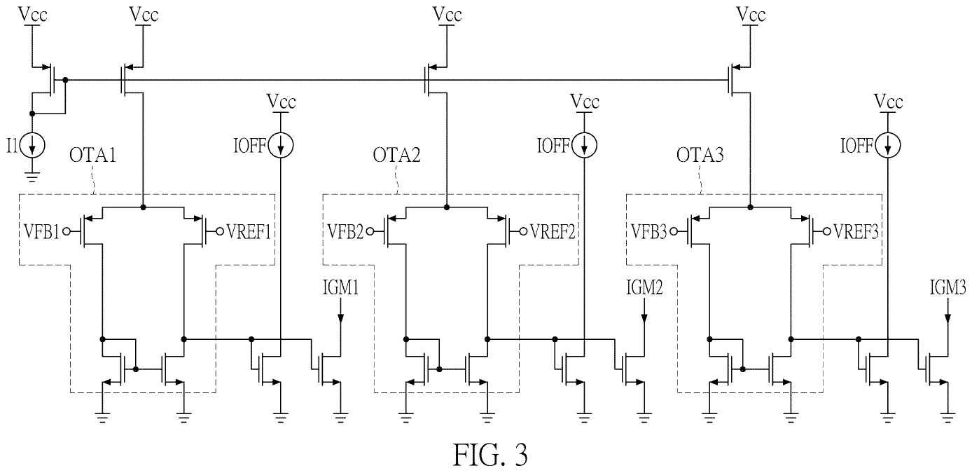

Reference is made to FIG. 3, which is a schematic diagram of an amplification stage circuit according to one embodiment of the present disclosure. FIG. 3 illustrates an implementation of the amplification stage circuit 10, and the first transconductance amplifier OTA1, the second transconductance amplifier OTA2, and the third transconductance amplifier OTA3 are respectively used as examples. A reference voltage and a feedback voltage are respectively input into the input terminals of each of the operational transconductance amplifiers. For example, the input terminal of the first operational transconductance amplifier OTA1 receives the first feedback voltage VFB1 and the first reference voltage VREF1, the input terminal of the second operational transconductance amplifier OTA2 receives the second feedback voltage VFB2 and the second reference voltage VREF2, and the input terminal of the third operational transconductance amplifier OTA3 receives the third feedback voltage VFB3 and the third reference voltage VREF3.

As shown in FIG. 3, the transconductance amplification current output by each of the operational transconductance amplifiers is respectively compensated. For example, the first transconductance amplification current IGM1 of the first transconductance amplifier OTA1 is represented by: IGM1=gm (VFB1−VREF1)+IOFF, the second transconductance amplification current IGM2 of the second transconductance amplifier OTA2 is represented by: IGM2=gm (VFB1−VREF2)+IOFF, and the third transconductance amplification current IGM3 of the third transconductance amplifier OTA3 is represented by: IGM3=gm (VFB3−VREF3)+IOFF.

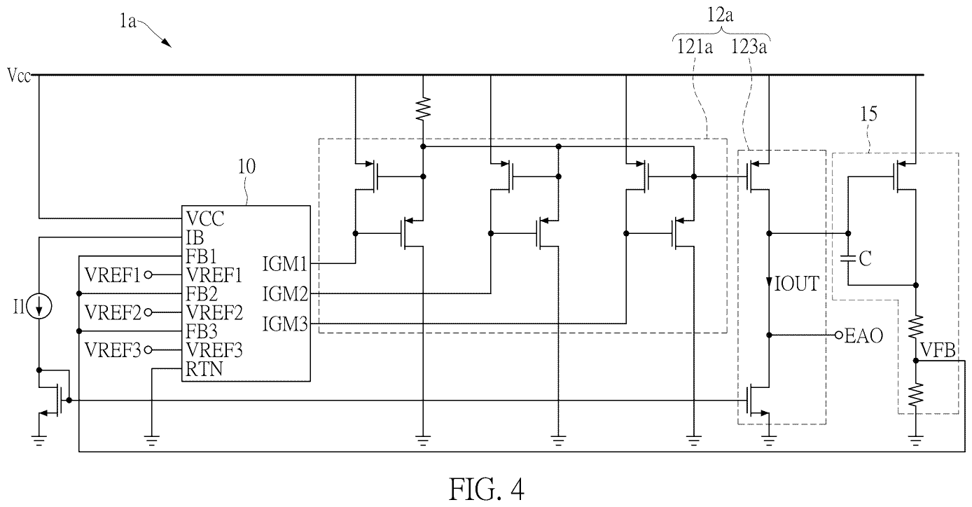

Referring to FIG. 4, FIG. 4 is a schematic diagram of a multi-loop control circuit according to one embodiment of the present disclosure. The amplification stage circuit 10 in FIG. 4 is a representation of multiple operational transconductance amplifiers in FIG. 1 integrated into a single circuit. The amplification stage circuit 10 is exemplified by using the voltage differences at three sets of input terminals. Components of the selection circuit 121a and the mapping circuit 123a in the current selection circuitry 12a are represented by P-channel transistor circuits. The operation principle of the current selection circuitry 12a is the same as the structure shown in FIG. 2 and will not be reiterated herein.

It should be noted that, the error amplification signal EAO passes through the feedback circuit 15 to generate the feedback voltage VFB, and the feedback circuit 15 then feeds back the feedback voltage VFB to the input terminals of each of the operational transconductance amplifiers in the amplification stage circuit 10. Taking the structure as shown in FIG. 4 as an example, the feedback circuit 15 is composed of a voltage divider circuit composed of resistors to obtain the feedback voltage VFB, and the feedback voltage VFB is used as the first feedback voltage VFB1 and the second feedback voltage VFB2, and the third feedback voltage VFB3 at the input terminals of each of the operational transconductance amplifiers.

Therefore, the largest transconductance amplification current is selected through the current selection circuitry 12a from a plurality of transconductance amplification currents output from each of the operational transconductance amplifiers and used as the error output current IOUT. The transconductance amplification current is then processed by the feedback circuit 15 to obtain the feedback voltage VFB, and each of the operational transconductance amplifiers compares the feedback voltage VFB with the reference voltage, such that the error amplification signal EAO output by a multi-loop control circuit 1a can track one of the reference voltages of the multiple operational transconductance amplifiers.

It can be understood that, according to the circuits shown in FIG. 1 and FIG. 3 of the present disclosure, the non-inverting input terminal of each of the operational transconductance amplifiers is used to receive the input of the feedback voltage VFB, and the inverting input terminal of each of the operational transconductance amplifiers is used to receive the input of the reference voltage. At this time, the error amplification signal EAO output by the multi-loop control circuit 1a tracks a maximum reference voltage among the multiple operational transconductance amplifiers.

In other embodiments, the inverting input terminal of each of the operational transconductance amplifiers can also be used to receive the input of the feedback voltage VFB, and the non-inverting input terminal of each of the operational transconductance amplifiers can be used to receive the input of the reference voltage. At this time, the error amplification signal EAO output by the multi-loop control circuit 1a tracks a minimum reference voltage among the multiple operational transconductance amplifiers.

### Examples of the Control Method of the Multi-Loop Control Circuit

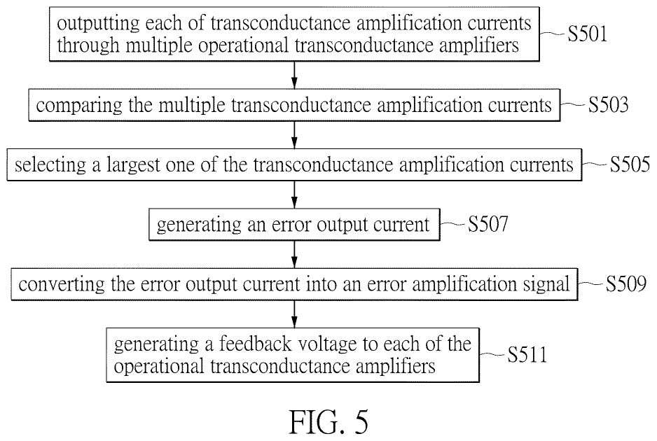

Reference is made to FIG. 5, which is a flowchart of a control method of a multi-loop control circuit according to one embodiment of the present disclosure. The embodiment of the present disclosure provides a flowchart for controlling a multi-loop control circuit. The process shown in FIG. 5 includes, such as but not limited to, the following descriptions of steps, and may be combined with reference to the structure of the multi-loop control circuit in the aforementioned embodiments.

Step S501 includes: outputting each of transconductance amplification currents through multiple operational transconductance amplifiers. Here, input terminals of each of the operational transconductance amplifiers each receive a reference voltage and a feedback voltage, and each of the operational transconductance amplifiers outputs a corresponding transconductance amplification current at an output terminal according to a voltage difference at the input terminals.

Step S503 includes: comparing the multiple transconductance amplification currents. Here, the transconductance amplification currents of each of the operational transconductance amplifiers are compared through a current selection circuitry.

Step S505 includes: selecting a largest one of the transconductance amplification currents. The current selection circuitry selects the largest one from each of the transconductance amplification currents.

Step S507 includes: generating an error output current. Here, the error output current is the maximum transconductance amplification current selected by the current selection circuitry.

Step S509 includes: converting the error output current into an error amplification signal. The error amplification signal is then transmitted to the next stage circuit through the node N.

Step S511 includes: generating a feedback voltage to each of the operational transconductance amplifiers. Here, the error amplification signal is divided to generate a feedback voltage through a feedback circuit, and the feedback voltage is output to the input terminals of each of the operational transconductance amplifier.

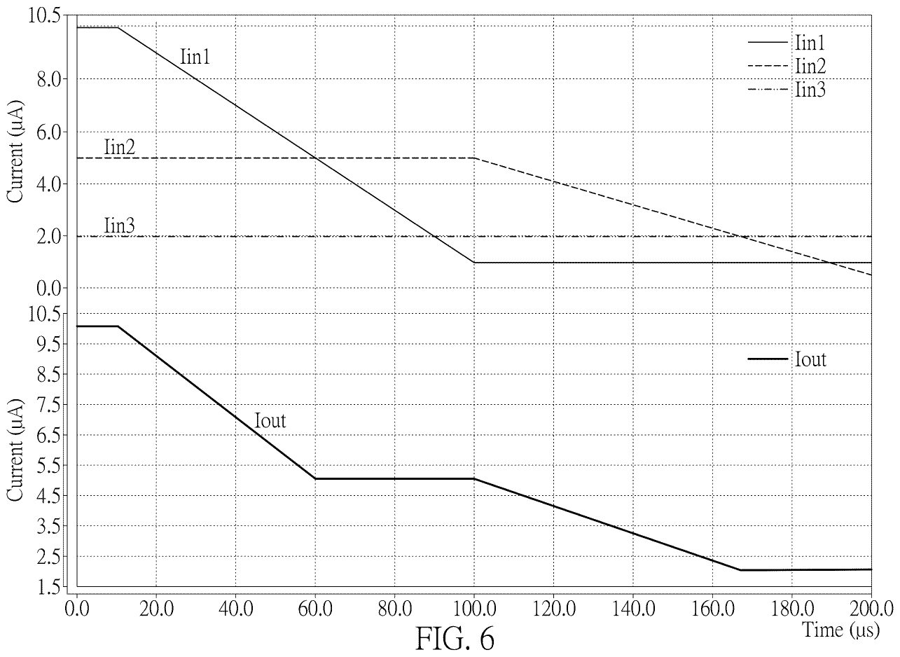

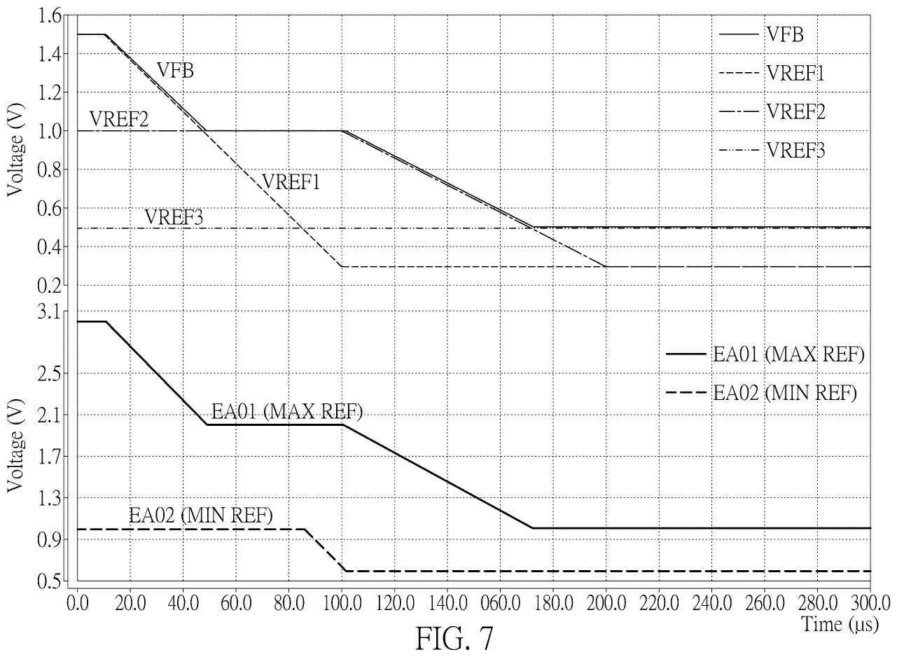

Next, conditions of the multi-loop control circuit in operation are shown by using examples. Here, a manner of connecting the voltages at the input terminal in the amplification stage circuit 10 is as shown in FIG. 1. Reference is further made to FIG. 6 and FIG. 7. FIG. 6 is a schematic diagram comparing waveforms of transconductance amplification currents and an error output current according to one embodiment of the present disclosure. FIG. 7 is a schematic diagram comparing waveforms of reference voltages and error amplification signals according to one embodiment of the present disclosure.

Firstly, reference is made to FIG. 6. The current selection circuitry 12 receives input currents Iin1, Iin2, and Iin3 respectively. Here, the input currents Iin1, Iin2, and Iin3 respectively represent the first transconductance amplification current IGM1 output by the first transconductance amplifier OTA1, the second transconductance amplification current IGM2 output by the second transconductance conduction amplifier OTA2, and the third transconductance amplification current IGM3 output by the third transconductance amplifier OTA3. Since the current selection circuitry 12 selects a largest one among the input currents Iin1, Iin2 and Iin3 to output, the current selection circuitry 12 selects the input current Iin1 that is the largest input current to output as the error output current IOUT from 0 μs to 60 μs. The current selection circuitry 12 selects the input current Iin2 that is the largest input current between 60 μs and 160 μs to output as the error output current IOUT, and the current selection circuitry 12 selects the input current Iin3 that is the largest input current between 160 μs and 200 μs to output as the error output current IOUT.

It can be understood that, the error output current IOUT of the current selection circuitry 12 of this embodiment will automatically output the largest one among the input currents Iin1, Iin2, and Iin3 with the changes of the input currents Iin1, Iin2, and Iin3.

Then, reference is made to FIG. 7. In FIG. 6, the error output current IOUT can be used to generate the error amplification signal EAO1 as shown in FIG. 7, and the error amplification signal EAO1 can generate the feedback voltage VFB as shown in FIG. 7 through the feedback circuit 15. The feedback voltage VFB is used as the input voltage of the non-inverting input terminal of each of the operational transconductance amplifiers through the circuit structure as shown in FIG. 1. In addition, the reference voltage received by the inverting input terminal of each of the operational transconductance amplifiers can be the first reference voltage VREF1 received by the first operational transconductance amplifier OTA1, the second reference voltage VREF2 received by the second operational transconductance amplifier OTA2, and the third reference voltage VREF3 received by the third operational transconductance amplifier OTA3 that are shown in FIG. 7.

Furthermore, under the control of the multi-loop control circuit of this embodiment, the error amplification signal EAO1 shown in FIG. 7 follows the maximum reference voltage of each of the operational transconductance amplifiers. For example, the error amplification signal EAO1 follows the first reference voltage VREF1 that is the maximum reference voltage from 0 μs to 48 μs, the error amplification signal EAO1 follows the second reference voltage VREF2 that is the maximum reference voltage from 48 μs to 100 μs, and the error amplification signal EAO1 follows the third reference voltage VREF3 that is the maximum reference voltage after 172 μs.

It should be noted that, when the input voltages of each of the operational transconductance amplifiers shown in FIG. 1 are reversely connected, for example, when the non-inverting input terminal of each of the operational transconductance amplifiers is changed to be connected to the reference voltage, and the inverting input terminal of each operational transconductance amplifier is changed to be connected to the feedback voltage, under the control of the multi-loop control circuit of this embodiment, an error amplification signal EAO2 shown in FIG. 7 follows the minimum reference voltage of each of the operational transconductance amplifiers. For example, the error amplification signal EAO2 follows the third reference voltage VREF3 that is the minimum reference voltage between 0 μs and 86 μs, and the error amplification signal EAO2 follows the first reference voltage VREF1 that is the minimum reference voltage after 86 μs.

### Beneficial Effects of the Embodiments

In conclusion, in the multi-loop control circuit and the control method of the multi-loop control circuit provided by the present disclosure, by the design of the current selection circuitry being disposed in the multi-loop control circuit, a quantity of the buffers that are used can be decreased, thereby effectively simplifying the space occupied by the circuitries and reducing power consumption. Furthermore, an electronic device using the multi-loop control circuit of the present disclosure can be effectively miniaturized.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multi-loop control circuit, comprising:
an amplification stage circuit including a first operational transconductance amplifier and a second operational transconductance amplifier, wherein the first operational transconductance amplifier generates a first transconductance amplification current at an output terminal based on a voltage difference at input terminals; wherein the second operational transconductance amplifier generates a second transconductance amplification current at an output terminal based on a voltage difference at input terminals; and
a current selection circuitry receiving the first transconductance amplification current and the second transconductance amplification current to output an error output current, wherein the current selection circuitry selects and outputs a largest one among the first transconductance amplification current and the second transconductance amplification current as the error output current, and an error amplification signal is generated from the error output current.

2. The multi-loop control circuit according to claim 1, wherein the current selection circuitry includes:
a selection circuit having a first switch circuit and a second switch circuit, wherein the first switch circuit generates a first conduction voltage based on the first transconductance amplification current, the second switch circuit generates a second conduction voltage based on the second transconductance amplification current, and the first switch circuit and the second switch circuit are connected in parallel to generate a conduction current; and
a mapping circuit mapping the conduction current of the selection circuit to generate the error output current;
wherein, when the first transconductance amplification current is greater than the second transconductance amplification current, the first conduction voltage is greater than the second conduction voltage, the first switch circuit is turned on based on the first conduction voltage, and the first conduction voltage clamps the second conduction voltage to turn off the second switch circuit; wherein the conduction current is the first transconductance amplification current;
wherein, when the second transconductance amplification current is greater than the first transconductance amplification current, the second conduction voltage is greater than the first conduction voltage, the second switch circuit is turned on based on the second conduction voltage, and the second conduction voltage clamps the first conduction voltage to turn off the first switch circuit; wherein the conduction current is the second transconductance amplification current.

3. The multi-loop control circuit according to claim 2, wherein the first switch circuit and the second switch circuit each include:
a first transistor having a control terminal, a first terminal, and a second terminal; and
a second transistor having a control terminal, a first terminal, and a second terminal;
wherein the first transistor of the first switch circuit forms the first conduction voltage at the first end and the second end of the first transistor based on the first transconductance amplification current, and the control terminal of the second transistor of the first switch circuit is controlled by the first conduction voltage; wherein, when the second transistor of the first switch circuit is turned on based on the first conduction voltage, the first transistor of the first switch circuit conducts the first transconductance amplification current;
wherein the first transistor of the second switch circuit forms the second conduction voltage at the first end and the second end of the first transistor based on the second transconductance amplification current, and the control terminal of the second transistor of the second switch circuit is controlled by the second conduction voltage; wherein, when the second transistor of the second switch circuit is turned on based on the second conduction voltage, the first transistor of the second switch circuit conducts the second transconductance amplification current;
wherein the control terminals of the first transistors in the first switch circuit and the second switch circuit are connected in parallel with each other.

4. The multi-loop control circuit according to claim 2, further comprising:
a current compensation circuit that respectively performs current compensation on the first transconductance amplification current and the second transconductance amplification current that flow into the current selection circuitry, so that the first transconductance amplification current and the second transconductance amplification current that are compensated each have positive levels.

5. The multi-loop control circuit according to claim 4, further comprising:
a current removal circuit removing a compensation current of the current compensation circuit from the error output current that flows out from the current selection circuitry.

6. The multi-loop control circuit according to claim 2, further comprising:
a feedback circuit generating a feedback voltage to the amplification stage circuit based on the error amplification signal.

7. The multi-loop control circuit according to claim 2, further comprising:
a loop compensation circuit connected to an output terminal of the current selection circuitry.

8. The multi-loop control circuit according to claim 2, wherein a non-inverting input terminal of the input terminal of the first operational transconductance amplifier receives a feedback voltage, and an inverting input terminal receives a first reference voltage; wherein a non-inverting input terminal of the input terminal of the second operational transconductance amplifier receives the feedback voltage, and an inverting input terminal receives a second reference voltage; and wherein a voltage level of the error amplification signal tracks a largest one among the first reference voltage and the second reference voltage and is changed synchronously.

9. The multi-loop control circuit according to claim 2, wherein an inverting input terminal of the input terminal of the first operational transconductance amplifier receives a feedback voltage, and a non-inverting input terminal receives a first reference voltage; wherein an inverting input terminal of the input terminal of the second operational transconductance amplifier receives the feedback voltage, and a non-inverting input terminal receives a second reference voltage; and wherein a voltage level of the error amplification signal tracks a smallest one among the first reference voltage and the second reference voltage and is changed synchronously.

10. A control method of a multi-loop control circuit, comprising:
comparing, by using a current selection circuitry, a first transconductance amplification current output by a first operational transconductance amplifier and a second transconductance amplification current output by a second operational transconductance amplifier;
outputting, by using the current selection circuitry, an error output current based on a result of the comparison, wherein the error output current is a largest one among the first transconductance amplification current and the second transconductance amplification current; and
converting the error output current into an error amplification signal.

11. The control method according to claim 10, wherein the process of comparing the first transconductance amplification current and the second transconductance amplification current by using the current selection circuitry further includes:
obtaining, through a first switch circuit and a second switch circuit in the current selection circuitry, the first transconductance amplification current and the second transconductance amplification current respectively, wherein the first switch circuit generates a first conduction voltage based on the first transconductance amplification current, the second switch circuit generates a second conduction voltage based on the second transconductance amplification current, and the first switch circuit and the second switch circuit are connected in parallel to generate a conduction current; and
mapping, by using a mapping circuit in the current selection circuitry, the conduction current to generate the error output current;
wherein, when the first transconductance amplification current is greater than the second transconductance amplification current, the first conduction voltage is greater than the second conduction voltage, the first switch circuit is turned on based on the first conduction voltage, and the first conduction voltage clamps the second conduction voltage to turn off the second switch circuit; wherein the conduction current is the first transconductance amplification current;
wherein, when the second transconductance amplification current is greater than the first transconductance amplification current, the second conduction voltage is greater than the first conduction voltage, the second switch circuit is turned on based on the second conduction voltage, and the second conduction voltage clamps the first conduction voltage to turn off the first switch circuit; wherein the conduction current is the second transconductance amplification current.

12. The control method according to claim 11, further comprising:
performing current compensation on the first transconductance amplification current and the second transconductance amplification current that flow into the current selection circuitry, so that the first transconductance amplification current and the second transconductance amplification current that are compensated each have positive levels; and
removing a compensation current from the error output current that flows out from the current selection circuitry.

13. The control method according to claim 11, further comprising:
generating a feedback voltage based on the error amplification signal to the first operational transconductance amplifier and the second operational transconductance amplifier.

14. The control method according to claim 11, wherein a non-inverting input terminal of the input terminal of the first operational transconductance amplifier receives a feedback voltage, and an inverting input terminal receives a first reference voltage; wherein a non-inverting input terminal of the input terminal of the second operational transconductance amplifier receives the feedback voltage, and an inverting input terminal receives a second reference voltage; and wherein a voltage level of the error amplification signal tracks a largest one among the first reference voltage and the second reference voltage and is changed synchronously.

15. The control method according to claim 11, wherein an inverting input terminal of the input terminal of the first operational transconductance amplifier receives a feedback voltage, and a non-inverting input terminal receives a first reference voltage; wherein an inverting input terminal of the input terminal of the second operational transconductance amplifier receives the feedback voltage, and a non-inverting input terminal receives a second reference voltage; and wherein a voltage level of the error amplification signal tracks a smallest one among the first reference voltage and the second reference voltage and is changed synchronously.
